(19) United States
(12) Patent Application Publication
(10) Pub. No.: US 2026/0277810 A1
(43) Pub. Date: Sep. 17, 2026

(54) THREE DIMENSIONAL STACKED PROCESSING UNIT

(71) Applicant: QUALCOMM Incorporated, San Diego, CA (US)

(72) Inventor: Raghava Rao DENDULURI, Cupertino, CA (US)

(21) Appl. No.: 19/530,146

(22) Filed: Feb. 4, 2026

Related U.S. Application Data
(60) Provisional application No. 63/772,221, filed on Mar. 14, 2025.

(51) Int. Cl. G06F 12/084; H10B 80/00; H10D 80/30; H10W 90/26

(52) U.S. Cl. CPC G06F 12/084; H10B 80/00; H10D 80/30; H10W 90/26

(57) ABSTRACT

Certain aspects of the present disclosure provide a stacked configuration for processing unit cores. According to certain aspects, an apparatus includes a stack of a first die and one or more additional dies; and at least one processing unit, comprising one or more processing cores and cache memory, distributed across at least two of the first die and the one or more additional dies.

### CROSS REFERENCE TO RELATED APPLICATION(S)

This application claims priority to U.S. Patent Application No. 63/772,221, filed Mar. 14, 2025, which is hereby incorporated by reference herein.

### TECHNICAL FIELD

Aspects of the present disclosure generally relate to techniques, apparatus, and embodiments for efficiently packaging processing unit components using stacked dies.

### BACKGROUND

A system on a chip (SoC) generally refers to an integrated circuit (IC) that combines various components of a computer system, such as a central processing unit (CPU), memory, and input/output ports onto a single chip. SoCs may also include other types of processing units, such as graphics processing units (GPUs) optimized for image processing and/or neural processing units (NPUs) optimized for artificial intelligence (AI) or machine learning (ML) operations.

SoCs essentially form a miniature computer on a single piece of silicon. SoCs typically achieve reduced power consumption, smaller size, and improved performance, when compared to systems using separate chips. As a result, SoCs are often used in applications that demand compact size and power efficiency, such as mobile devices, tablets, wearable devices, IoT (Internet of Things) devices, automotive, and various types of embedded systems.

### BRIEF SUMMARY

One aspect provides an apparatus. The apparatus includes a stack of a first die and one or more additional dies, and at least one processing unit, comprising one or more processing cores and cache memory, distributed across at least two of the first die and the one or more additional dies.

One aspect provides an apparatus. The apparatus includes a first die configured with a first set of functionalities; an interface that supports different types of processor architectures; and at least one additional die having one or more processor cores of one of the different types of processor architectures, wherein the one or more processor cores are configured to access the first set of functionalities via the interface.

Another aspect provides a method generally including: forming a first die configured with a first set of functionalities; forming an interface on the first die that supports different types of processor architectures; forming at least one additional die having one or more processor cores of one of the different types of processor architectures; and forming a processing unit by stacking the first die and the at least one additional die, wherein the one or more processor cores are configured to access at least one of the first set of functionalities via the interface.

Another aspect provides a base die configured with a first set of functionalities; an interface formed on the base die that supports different types of processor architectures; and at least one additional die having one or more processor cores of one of the different types of processor architectures, wherein the one or more processor cores are configured to access the first set of functionalities via the interface.

Other aspects provide: an apparatus operable, configured, or otherwise adapted to perform any one or more of the aforementioned methods and/or those described elsewhere herein; a non-transitory, computer-readable media comprising instructions that, when executed (e.g., directly, indirectly, after pre-processing, without pre-processing) by one or more processors of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

The following description and the related drawings set forth in detail certain illustrative features of one or more aspects.

### BRIEF DESCRIPTION OF THE DRAWINGS

The appended figures depict certain features of one or more aspects of the present disclosure and are therefore not to be considered limiting of the scope of this disclosure.

FIG. 1 depicts an example CPU cluster according to various aspects of the present disclosure.

FIG. 2 depicts an example 2-dimensional (2D) CPU cluster configuration.

FIG. 3 depicts an example 3-dimensional (3D) stacked CPU cluster configuration according to various aspects of the present disclosure.

FIG. 4 illustrates example reductions in planar dimensions achievable using a 3D stacked CPU cluster configuration according to various aspects of the present disclosure.

FIGS. 5A, 5B, and 5C depict example stack options according to various aspects of the present disclosure.

FIGS. 6A, 6B, and 6C depict side views of example 3D stack configurations according to various aspects of the present disclosure.

FIG. 6D depicts various options for 3D stack configurations according to various aspects of the present disclosure.

FIG. 7 depicts an example 3D stack configuration, according to various aspects of the present disclosure

To facilitate understanding, identical reference numerals have been used, where possible, to designate identical elements that are common to the drawings. It is contemplated that elements and features of one aspect may be beneficially incorporated in other aspects without further recitation.

### DETAILED DESCRIPTION

Aspects of the present disclosure generally relate to techniques and apparatus for efficiently packaging processing unit components using stacked dies.

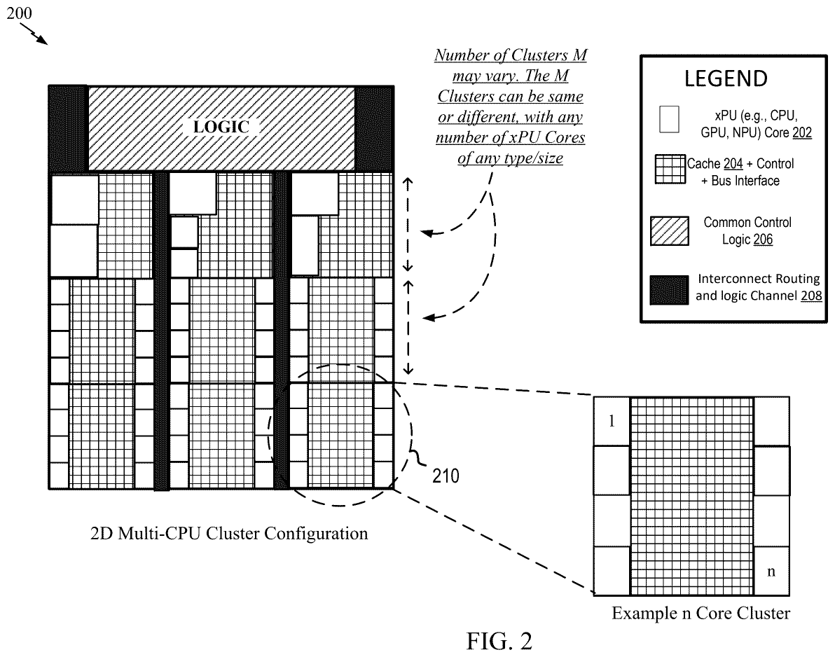

In some cases, various components of an SoC may be formed using a 2-dimensional (2D) configuration 200 on a single silicon die, as illustrated in FIG. 2. As indicated in the legend, clusters may include a set of CPU cores 202 arranged around a cache (e.g., an L2 cache 204). An SoC may include M clusters of CPUs, with each cluster containing n cores. In the illustrated example, there are M=9 clusters of xPUs. In this context, an xPU may refer to any type of processing unit (PU), such as a central processing unit (CPU, where x=C), graphics processing unit (GPU, where x=G), tensor processing unit (TPU, where x=T), or neural processing unit (NPU, where x=N).

The M clusters may be the same or different. In the illustrated example, some clusters 210 have n=8 of the same (e.g., CPU) cores, one cluster has n=2 of the same type of core, one cluster has n=3 cores of two different types (e.g., GPU and/or NPU), while one cluster has n=2 cores of two different types. Interconnect routing and logic channels 208 may allow the clusters to communicate. The SoC may also include additional logic (e.g., common control logic 206).

Aspects of the present disclosure provide a 3D stacked configuration (of stacked dies) that may provide various advantages. For example, by “lifting” or “raising” cores to a different die (e.g., than other logic on a base die), overall planar dimensions may be reduced. Further, in some cases, xPU cores (or core parts) may be implemented on dies using optimal process nodes.

In some cases, such arrangements may be implemented as chiplets that provide design flexibility. A chiplet generally refers to a small, modular IC designed to perform a certain function and can be combined with other chiplets to create a larger, more complex system-on-chip (SoC). Using the stacking techniques proposed herein, chiplets may serve as efficient processing building blocks and may be combined within a single package.

The 3D stacking approach may provide substantial flexibility and allow for customization in chip design with reduced design and implementation timelines. Using the techniques proposed herein, different arrangements may be optimized for different use cases, such as mobile devices, tablets, wearable devices, IoT (Internet of Things) devices, and automotive applications.

### Example CPU Cluster

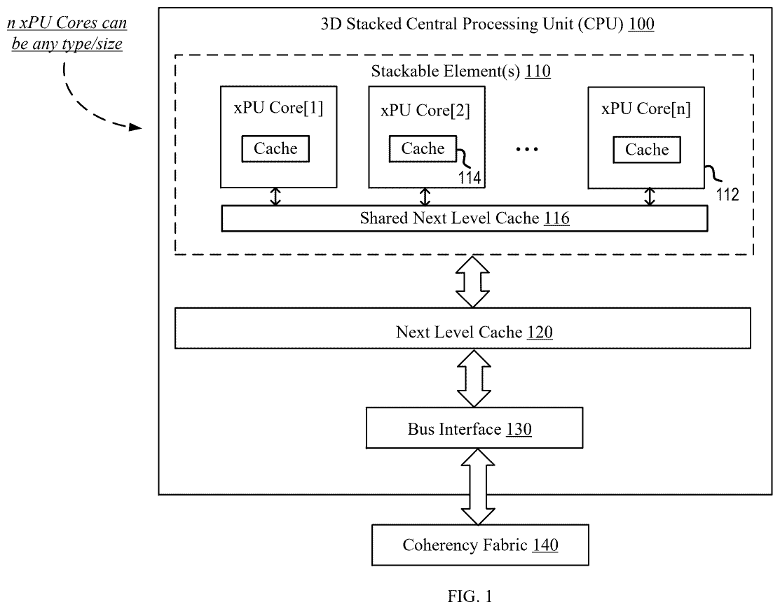

FIG. 1 depicts a block diagram of an example 3D stacked CPU 100 that may be configured according to certain aspects of the present disclosure. For example, the three dimensional (3D) stacking techniques proposed herein may be used to reduce overall planar dimensions (e.g., size/footprint) of a design (e.g., of an SoC) that includes one or more stackable elements 110.

As illustrated, a stackable element 110 may be formed with n xPU cores (labeled xPU Core[1] to xPU Core[n]), where n can be any integer number and the actual value may depend on a particular design or design constraints.

Each xPU Core may include a local cache 114 and, in some cases, may share a next level cache (NLC) 116 with the other cores. According to certain aspects, there may be a separate NLC 120 (e.g., shared by multiple stackable elements). An NLC may be, for example, some form of a last level cache (LLC)) having a much larger storage capacity compared to the local caches 114.

The CPU cluster 100 may include a bus interface 130. The bus interface 130 may be a physical (and logical) interface that connects CPU 100 to other components. For example, the bus interface 130 may connect the respective CPU to a coherency fabric 140 (e.g., system bus) that connects the respective CPU to another CPU cluster (not shown) as well as other components, such as main memory.

### Example 3D Stacked xPU Configuration

As noted above with reference to FIG. 2, various components of an SoC may be formed using a 2D configuration on a single silicon die. Aspects of the present disclosure, however, provide a 3D stacked configuration that may provide various advantages.

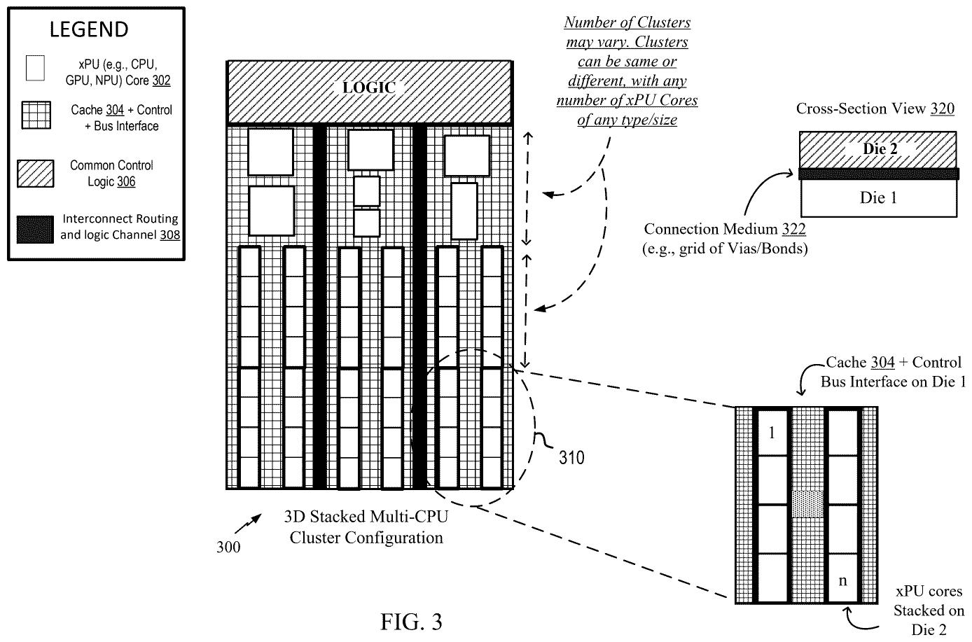

For example, FIG. 3 illustrates an example 3D configuration 300 in accordance with aspects of the present disclosure. Similar to the example shown in FIG. 2, a cluster 310 may include a set of xPU cores and a cache.

The illustrated configuration has clusters with a same number and similar configurations of cores as FIG. 2, but in a stacked 3D arrangement. For example, some clusters 310 have n=8 of the same (e.g., CPU) cores 302, one cluster has n=2 of the same type of core, one cluster has n=3 cores of two different types (e.g., GPU and/or NPU), while one cluster has n=2 cores of two different types.

As indicated in FIG. 3, using a stacked approach, the cache 304 and cores 302 may be on different dies. As an example, the cache may be implemented on a first die (e.g., Die 1, what may be referred to as a base die) at the bottom of an SoC package), while the cores may be stacked above (e.g., “raised” or “lifted”) on another die, Die 2, on top of the base die. In some cases, the base die may be (stacked) on top of one or more dies that include cores.

In the illustrated example, a 4 CPU core strip may be considered a stackable element (and each cluster 310 may have 2 such elements, for 8 cores total (e.g., n=8).

As shown in the cross-section view 320, any suitable type of connection medium 322 (e.g., a grid of vias and/or bonds) may formed between dies (e.g., Die 1 and Die 2) and used to connect (allow communication between) the components on the different dies.

In some cases, an interface may be formed, allowing a first set of functionalities formed on Die 1 to communicate with a second set of functionalities formed on Die 2, via medium 322. The interface may be formed, for example, as part of control bus interface, common control logic 306, and/or interconnect routing and logic channel(s) 308. As will be described in greater detail below, in some cases, the interface may support different types of processor architectures. As a result, the base die (Die 1) may be considered agnostic with regard to processor architecture, providing flexibility for the same base die to accommodate additional dies with functionality in-line with different processor architectures.

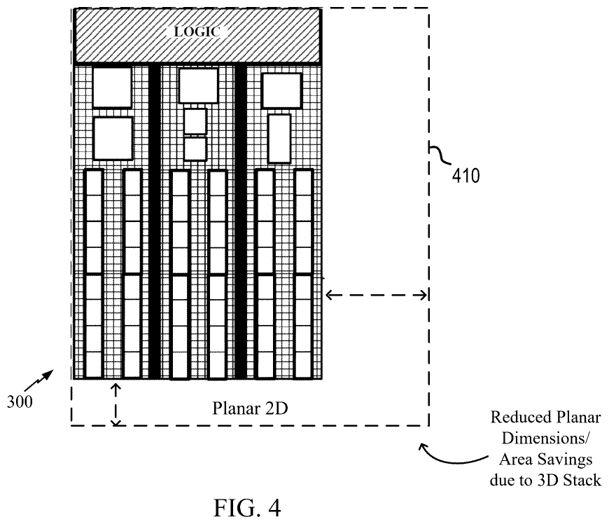

The example configurations shown in FIG. 2 and FIG. 3 each have 9 clusters, with similar numbers and types of cores in each. As illustrated in FIG. 4, however, the 3D stacked configuration shown in FIG. 3 has reduced planar dimensions, resulting in significant area savings (as indicated at 410) relative to the planar 2D configuration shown in FIG. 2. The reduced dimensions may provide additional design and packaging flexibility.

As described above, cores (or core parts) of different xPUs may be arranged as stackable elements according to various options.

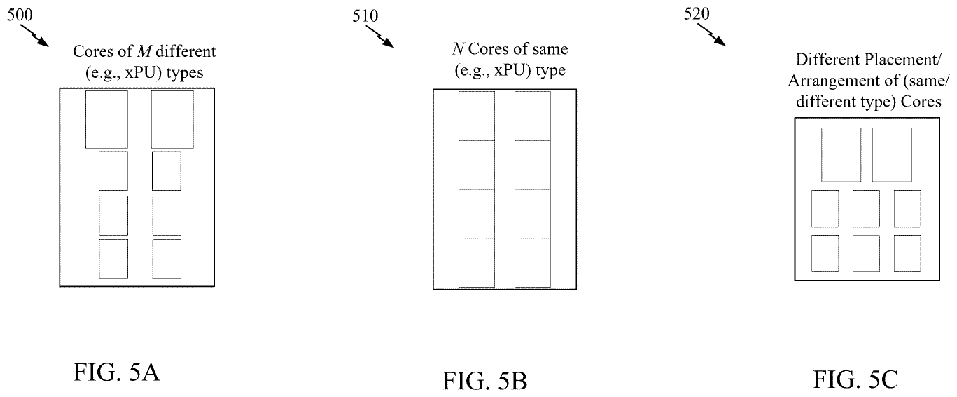

As illustrated in diagram 500 of FIG. 5A, cores of M different xPU types may be arranged on one die (in the illustrated example, M=2). As illustrated in diagram 510 of FIG. 5B, N cores of a same xPU type may be arranged on one die (in the illustrated example, N=8 a 2 4-core strips). As illustrated in diagram 520 of FIG. 5C, different arrangements of the same or different types of cores are also possible (in the illustrated example, the same number and type of cores as FIG. 5A are shown, but in a different arrangement).

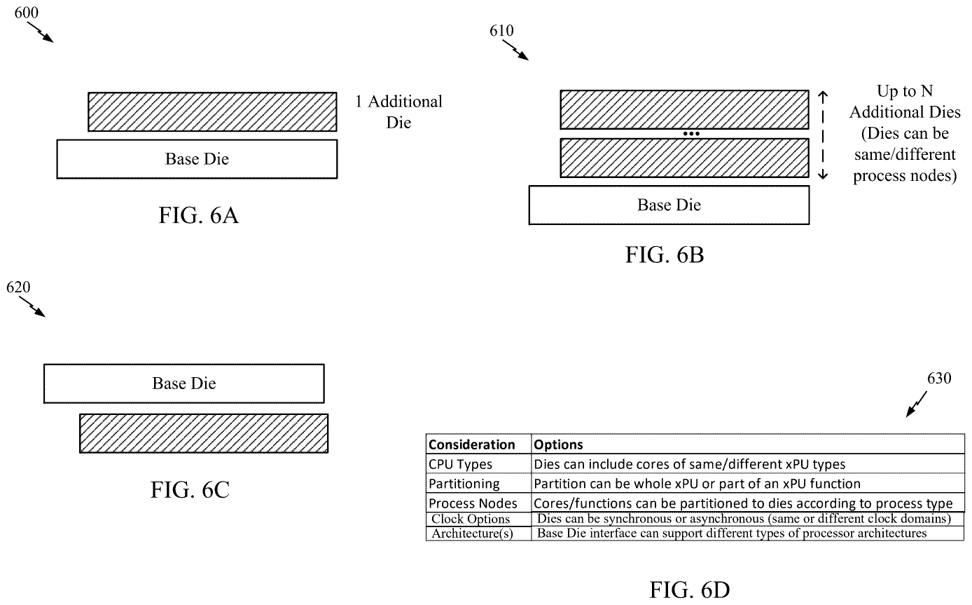

FIG. 6A illustrates an example side view 600 of a stacked arrangement according to aspects of the present disclosure. In this relatively simple example, a single additional die is arranged above a base die. As illustrated in the example side view 620 of FIG. 6B, more generally, N additional dies may be arranged above a base die. As illustrated in the example side view of FIG. 6C, in some cases a base die may be on top (above one or more additional dies).

As illustrated in table 630 of FIG. 6D, there are various options for how to distribute xPU cores and/or core functionalities across different dies.

The stackable techniques described herein may be used to distribute the same or different types of quantities of such xPUs across different dies in a stack. Similarly, the techniques described herein may also be used to distribute different processor resources (e.g., such as memory resources) or particular functionality (e.g., shader functionality of a GPU) of such xPUs across different dies in a stack.

In one stacked configuration, a CPU (core cluster) may be stacked on top of the cache. For example, the CPU cores may be on a top die, while the cache is on a different die (e.g., the base die). In an alternative configuration, this could be reversed (e.g., with the cache stacked on top of the CPU).

Further, in some cases, xPU cores (or core parts) may be implemented on dies using optimal process nodes. In the context of semiconductor processing, a process node generally refers to a size of the smallest feature on a transistor. As such, a process node typically signifies a specific manufacturing process used to create a new generation of chips with smaller transistors, leading to increased performance and power efficiency. A lower process node number indicates smaller features and more advanced technology.

In the stacked configurations proposed herein, dies configured with more modern (and expensive) process nodes may be reserved for cores (or core functionalities) that require the corresponding features. Thus, cost may be reduced by relegating other cores (or core functionalities) to dies configured with older (and less expensive) process nodes.

As indicated in table 630 of FIG. 6D, in some cases, top and bottom dies may be synchronous (e.g., with a same clock domain). In other cases, top and bottom dies may be asynchronous (e.g., with different clock domains). Whether dies are synchronous or asynchronous may be an implementation-specific decision based on a particular configuration.

As indicated in table 630 of FIG. 6D, and as noted above, a base die may have an interface that supports different types of processor architectures. In other words, this interface may allow functionality on the base die to communicate with different types of processor architectures on one or more additional dies. In this context, such a base die may be considered “processor architecture agnostic.”

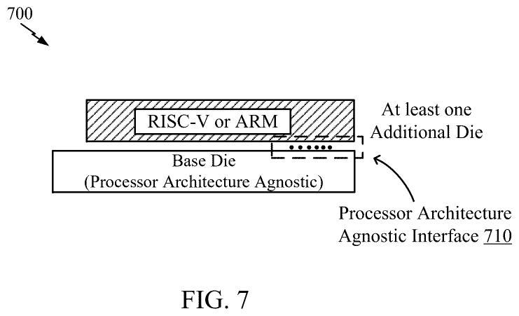

FIG. 7 illustrates an example 3D stack 700 with such an agnostic interface 710 that may support different types of processor architectures. The interface 710 may include any suitable type of bus configuration, interconnection, and control logic.

For example, the interface may allow the base die to communicate with functionality on an additional die according to different types of Reduced Instruction Set Computer (RISC) instruction set architectures (ISAs). Examples of such architectures include the proprietary Advanced RISC Machine (ARM) architecture and open standard RISC-V (where the Roman numeral V indicates 5^{th} generation). The flexibility to accommodate different architectures with a same base die may provide design flexibility for customization and reduce time to market.

In some cases, dies used in stacked arrangements may be implemented as chiplets that provide design flexibility. A chiplet generally refers to a small, modular IC designed to perform a certain function and can be combined with other chiplets to create a larger, more complex SoC. Using the stacking techniques proposed herein, chiplets may serve as efficient processing building blocks and may be combined within a single package. Using smaller chiplets in this manner may also help achieve greater yield from a silicon wafer, with reduced waste and corresponding cost.

Each chiplet or combination of chiplets may be considered separate intellectual property (IP) available to a designer. In chip design, IP generally refers to pre-designed and verified building blocks of logic or circuits that can be reused in the creation of a semiconductor chip, essentially acting as reusable components that companies can license or integrate into their larger chip designs to save time and cost during development

As described herein, the 3D stacking approach may provide substantial flexibility and allow for customization in chip design with reduced design and implementation timelines. Using the techniques proposed herein, different arrangements may be optimized for different use cases, such as mobile devices, tablets, wearable devices, IoT (Internet of Things) devices, and automotive applications.

### Example Clauses

Implementation examples are described in the following numbered clauses:

Clause 1: A three-dimensional (3D) stacked processing unit, comprising a first die configured with a first set of functionalities; an interface that supports different types of processor architectures; and at least one additional die having one or more processor cores of one of the different types of processor architectures, wherein the one or more processor cores are configured to access the first set of functionalities via the interface.

Clause 2: The 3D stacked processing unit of Clause 1, wherein the first set of functionalities involves at least one of memory functionality or processing functionality.

Clause 3: The 3D stacked processing unit of Clause 2, wherein the first set of functionalities provides access to cache memory formed on the first die.

Clause 4: The 3D stacked processing unit of any one of Clauses 1-3, wherein the different types of processor architectures supported by the interface comprise: a first processor architecture that implements a first instruction set architecture (ISA); and a second processor architecture that implements a second ISA.

Clause 5: The 3D stacked processing unit of Clause 4, wherein: the first ISA comprises a proprietary ISA; and the first ISA comprises an open ISA.

Clause 6: The 3D stacked processing unit of any one of Clauses 1-5, wherein the at least one additional die comprises: a first chiplet having one or more processor cores formed thereon, wherein the first chiplet is provided by a first vendor.

Clause 7: The 3D stacked processing unit of Clause 6, wherein the at least one additional die further comprises: a second chiplet having one or more processor cores formed thereon, wherein the second chiplet is provided by a second vendor.

Clause 8: The 3D stacked processing unit of any one of Clauses 1-7, wherein: the first functionality configured on the first die operates via a first clock domain; and the one or more processor cores of the at least one additional die operate via a second clock domain.

Clause 9: A method, comprising: forming a first die configured with a first set of functionalities; forming an interface on the first die that supports different types of processor architectures; forming at least one additional die having one or more processor cores of one of the different types of processor architectures; and forming a processing unit by stacking the first die and the at least one additional die, wherein the one or more processor cores are configured to access at least one of the first set of functionalities via the interface.

Clause 10: The method of Clause 9, wherein the first set of functionalities involves at least one of memory functionality or processing functionality.

Clause 11: The method of Clause 10, wherein the first set of functionalities provides access to cache memory formed on the first die.

Clause 12: The method of any one of Clauses 9-11, wherein the different types of processor architectures supported by the interface comprise: a first processor architecture that implements a first instruction set architecture (ISA); and a second processor architecture that implements a second ISA.

Clause 13: The method of Clause 12, wherein: the first ISA comprises a proprietary ISA; and the first ISA comprises an open ISA.

Clause 14: The method of any one of Clauses 9-13, wherein the at least one additional die comprises: a first chiplet having one or more processor cores formed thereon, wherein the first chiplet is provided by a first vendor.

Clause 15: The method of Clause 14, wherein the at least one additional die further comprises: a second chiplet having one or more processor cores formed thereon, wherein the second chiplet is provided by a second vendor.

Clause 16: The method of any one of Clauses 9-15, wherein: the first functionality configured on the first die operates via a first clock domain; and the one or more processor cores of the at least one additional die operate via a second clock domain.

Clause 17: A processing unit, comprising: a base die configured with a first set of functionalities; an interface formed on the base die that supports different types of processor architectures; and at least one additional die having one or more processor cores of one of the different types of processor architectures, wherein the one or more processor cores are configured to access the first set of functionalities via the interface.

Clause 18: The processing unit of Clause 17, wherein the first set of functionalities involves at least one of memory functionality or processing functionality.

Clause 19: The processing unit of Clause 18, wherein the first set of functionalities provides access to cache memory formed on the first die.

Clause 20: The processing unit of any one of Clauses 17-19, wherein the different types of processor architectures supported by the interface comprise: a first processor architecture that implements a first instruction set architecture (ISA); and a second processor architecture that implements a second ISA.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the generic principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, the word “exemplary” means “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A three-dimensional (3D) stacked processing unit, comprising:
a first die configured with a first set of functionalities;
an interface that supports different types of processor architectures; and
at least one additional die having one or more processor cores of one of the different types of processor architectures, wherein the one or more processor cores are configured to access the first set of functionalities via the interface.

2. The 3D stacked processing unit of claim 1, wherein the first set of functionalities involves at least one of memory functionality or processing functionality.

3. The 3D stacked processing unit of claim 2, wherein the first set of functionalities provides access to cache memory formed on the first die.

4. The 3D stacked processing unit of claim 1, wherein the different types of processor architectures supported by the interface comprise:
a first processor architecture that implements a first instruction set architecture (ISA); and
a second processor architecture that implements a second ISA.

5. The 3D stacked processing unit of claim 4, wherein:
the first ISA comprises a proprietary ISA; and
the first ISA comprises an open ISA.

6. The 3D stacked processing unit of claim 1, wherein the at least one additional die comprises:
a first chiplet having one or more processor cores formed thereon, wherein the first chiplet is provided by a first vendor.

7. The 3D stacked processing unit of claim 6, wherein the at least one additional die further comprises:
a second chiplet having one or more processor cores formed thereon, wherein the second chiplet is provided by a second vendor.

8. The 3D stacked processing unit of claim 1, wherein:
the first functionality configured on the first die operates via a first clock domain; and
the one or more processor cores of the at least one additional die operate via a second clock domain.

9. A method, comprising:
forming a first die configured with a first set of functionalities;
forming an interface on the first die that supports different types of processor architectures;
forming at least one additional die having one or more processor cores of one of the different types of processor architectures; and
forming a processing unit by stacking the first die and the at least one additional die, wherein the one or more processor cores are configured to access at least one of the first set of functionalities via the interface.

10. The method of claim 9, wherein the first set of functionalities involves at least one of memory functionality or processing functionality.

11. The method of claim 10, wherein the first set of functionalities provides access to cache memory formed on the first die.

12. The method of claim 9, wherein the different types of processor architectures supported by the interface comprise:
a first processor architecture that implements a first instruction set architecture (ISA); and
a second processor architecture that implements a second ISA.

13. The method of claim 12, wherein:
the first ISA comprises a proprietary ISA; and
the first ISA comprises an open ISA.

14. The method of claim 9, wherein the at least one additional die comprises:
a first chiplet having one or more processor cores formed thereon, wherein the first chiplet is provided by a first vendor.

15. The method of claim 14, wherein the at least one additional die further comprises:
a second chiplet having one or more processor cores formed thereon, wherein the second chiplet is provided by a second vendor.

16. The method of claim 9, wherein:
the first functionality configured on the first die operates via a first clock domain; and
the one or more processor cores of the at least one additional die operate via a second clock domain.

17. A processing unit, comprising:
a base die configured with a first set of functionalities;
an interface formed on the base die that supports different types of processor architectures; and
at least one additional die having one or more processor cores of one of the different types of processor architectures, wherein the one or more processor cores are configured to access the first set of functionalities via the interface.

18. The processing unit of claim 17, wherein the first set of functionalities involves at least one of memory functionality or processing functionality.

19. The processing unit of claim 18, wherein the first set of functionalities provides access to cache memory formed on the first die.

20. The processing unit of claim 17, wherein the different types of processor architectures supported by the interface comprise:
a first processor architecture that implements a first instruction set architecture (ISA); and
a second processor architecture that implements a second ISA.
